(19) United States
(12) Patent Application Publication
(10) Pub. No.: US 2024/0128264 A1
(43) Pub. Date: Apr. 18, 2024

(54) SEMICONDUCTOR DEVICES

(71) Applicant: Samsung Electronics Co., Ltd., Suwon-si (KR)

(72) Inventors: Ji Min Yu, Suwon-si (KR); Heon Jong Shin, Suwon-si (KR); Doo Hyun Lee, Suwon-si (KR)

(21) Appl. No.: 18/331,296

(22) Filed: Jun. 8, 2023

(30) Foreign Application Priority Data
Oct. 12, 2022 (KR) 10-2022-0130577
Feb. 9, 2023 (KR) 10-2023-0017185

(51) Int. Cl. H01L 27/088; H01L 21/8234; H01L 29/06; H01L 29/423; H01L 29/66; H01L 29/775

(52) U.S. Cl. CPC H01L 27/088; H01L 21/823412; H01L 21/823481; H01L 29/0673; H01L 29/42392; H01L 29/66439; H01L 29/66545; H01L 29/775

(57) ABSTRACT

A semiconductor device includes a substrate, first and second active patterns extending in a first horizontal direction on the substrate, first and second gate electrodes extending in a second horizontal direction on the first and second active patterns, respectively, a first trench extending in the second horizontal direction between the first and second gate electrodes and separating the first and second active patterns, at least part of the first trench is in the substrate, an active cut extending along sidewalls and a bottom surface of the first trench and contacting each of the first and second active patterns, a second trench on the active cut in the first trench, and a flowable material layer in at least part of the second trench, the flowable material layer including a flowable insulating material and not being in contact with each of the substrate and the first and second active patterns.

### CROSS-REFERENCE TO RELATED APPLICATION

This application claims priority from Korean Patent Application No. 10-2022-0130577 filed on Oct. 12, 2022 and Korean Patent Application No. 10-2023-0017185 filed on Feb. 9, 2023 in the Korean Intellectual Property Office, and all the benefits accruing therefrom under 35 U.S.C. 119, the contents of which in their entirety are herein incorporated by reference.

### BACKGROUND

The present disclosure relates to semiconductor devices, and more particularly, to semiconductor devices including a Multi-Bridge Channel Field Effect Transistor (MBCFET™) and methods of fabricating the same.

As a scaling technique for increasing the density of a semiconductor device, a multi-gate transistor has been suggested in which a fin- or nanowire-type silicon body is formed on a substrate and a gate is formed on the surface of the multi-channel active pattern.

Since the multi-gate transistor uses a three-dimensional (3D) channel, scaling can be facilitated. Also, current control capability can be improved without increasing the length of the gate of the multi-gate transistor. Also, a short channel effect (SCE), i.e., the phenomenon of the potential of a channel region being affected by a drain voltage, can be effectively suppressed.

### SUMMARY

Aspects of the present disclosure provide semiconductor devices having an active cut filled with a flowable insulating material, which includes a material having the same tensile or compressive stress as an interlayer insulating layer in the active cut, and is thereby capable of preventing defects in source/drain contacts by preventing the active cut from being expanded horizontally.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the present disclosure, there is provided a semiconductor device comprising a substrate, a first active pattern that extends in a first horizontal direction on the substrate, a second active pattern that extends in the first horizontal direction on the substrate, the second active pattern is spaced apart from the first active pattern in the first horizontal direction, a first gate electrode that extends in a second horizontal direction different from the first horizontal direction on the first active pattern, a second gate electrode that extends in the second horizontal direction on the second active pattern, a first trench that extends in the second horizontal direction between the first gate electrode and the second gate electrode, the first trench separates the first active pattern and the second active pattern, and at least part of the first trench is in the substrate, an active cut that extends along sidewalls and a bottom surface of the first trench, the active cut is in contact with each of the first active pattern and the second active pattern, a second trench on the active cut in the first trench, and a flowable material layer in at least part of the second trench, the flowable material layer includes a flowable insulating material, and the flowable material layer is not in contact with each of the substrate, the first active pattern, and the second active pattern.

According to some embodiments of the present disclosure, there is provided a semiconductor device comprising a substrate, a first active pattern that extends in a first horizontal direction on the substrate, a second active pattern that extends in the first horizontal direction on the substrate, the second active pattern is spaced apart from the first active pattern in the first horizontal direction, a first gate electrode that extends in a second horizontal direction different from the first horizontal direction on the first active pattern, a gate capping pattern that extends in the second horizontal direction on a top surface of the first gate electrode, an active cut spaced apart from the first gate electrode in the first horizontal direction, the active cut separates the first active pattern and the second active pattern, the active cut is in contact with each of the first active pattern and the second active pattern, at least part of the active cut is in the substrate, and a top surface of the active cut is coplanar with a top surface of the gate capping pattern, a flowable material layer in the active cut, the flowable material layer includes a flowable insulating material, the flowable material layer is not in contact with each of the substrate, the first active pattern, and the second active pattern, and a top surface of the flowable material layer is lower than the top surface of the active cut relative to the substrate, and an active cut capping pattern on the flowable material layer in the active cut, the active cut capping pattern includes a material different from that of the flowable material layer.

According to some embodiments of the present disclosure, there is provided a semiconductor device comprising a substrate, a first active pattern that extends in a first horizontal direction on the substrate, a second active pattern that extends in the first horizontal direction on the substrate, the second active pattern is spaced apart from the first active pattern in the first horizontal direction, a first plurality of nanosheets spaced apart from one another in a vertical direction perpendicular to the first horizontal direction on the first active pattern, a second plurality of nanosheets spaced apart from one another in the vertical direction on the second active pattern, a third plurality of nanosheets spaced apart from one another in the vertical direction on the first and second active patterns, a first gate electrode that extends in a second horizontal direction different from the first horizontal direction on the first active pattern, the first gate electrode at least partially surrounds the first plurality of nanosheets, a second gate electrode that extends in the second horizontal direction on the second active pattern, the second gate electrode at least partially surrounds the second plurality of nanosheets, a third gate electrode that extends in the second horizontal direction on the first and second active patterns, the third gate electrode at least partially surrounds the third plurality of nanosheets, a first trench that extends into the third gate electrode, the third plurality of nanosheets, and the substrate in the vertical direction, the first trench extends in the second horizontal direction between the first gate electrode and the second gate electrode, and the first trench separates the first active pattern and the second active pattern, an active cut that extends along sidewalls and a bottom surface of the first trench, the active cut is in contact with each of the first active pattern, the second active pattern, the third gate electrode, and the third plurality of nanosheets, a second trench on the active cut in the first trench, a flowable material layer in at least part of the second trench, the flowable material layer includes a flowable insulating material, and the flowable material layer is not in contact with each of the substrate, the first active pattern, and the second active pattern, and an active cut capping pattern on the flowable material layer in the active cut, the active cut capping pattern includes a material different from that of the flowable material layer.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout view of a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIGS. 4 through 21 are cross-sectional views illustrating intermediate steps of a method of fabricating a semiconductor device according to some embodiments of the present disclosure;

FIG. 22 is a cross-sectional view of a semiconductor device according to some embodiments of the present disclosure;

FIG. 23 is a cross-sectional view of a semiconductor device according to some embodiments of the present disclosure;

FIG. 24 is a cross-sectional view of a semiconductor device according to some embodiments of the present disclosure;

FIG. 25 is a cross-sectional view of a semiconductor device according to some embodiments of the present disclosure;

FIG. 26 is a cross-sectional view of a semiconductor device according to some embodiments of the present disclosure; and

FIGS. 27 and 28 are cross-sectional views of a semiconductor device according to some embodiments of the present disclosure.

### DETAILED DESCRIPTION

A semiconductor device according to some embodiments of the present disclosure will hereinafter be described as including a Multi-Bridge Channel Field Effect Transistor (MBCFET™) including nanosheets or a fin field-effect transistor (FinFET) including fin-type channel regions, but the present disclosure is not limited thereto. A semiconductor device according to other embodiments of the present disclosure may include a tunneling field-effect transistor (FET) or a three-dimensional (3D) transistor. A semiconductor device according to other embodiments of the present disclosure may include a bipolar junction transistor or a lateral double-diffused metal-oxide-semiconductor field-effect transistor (LDMOS).

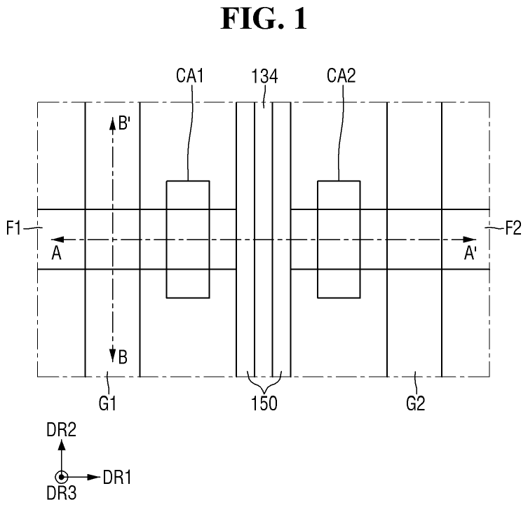

A semiconductor device according to some embodiments of the present disclosure will hereinafter be described with reference to FIGS. 1 through 6.

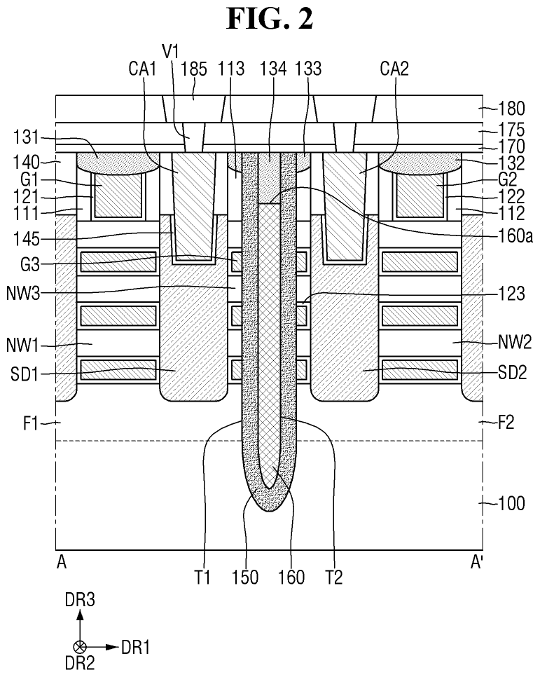

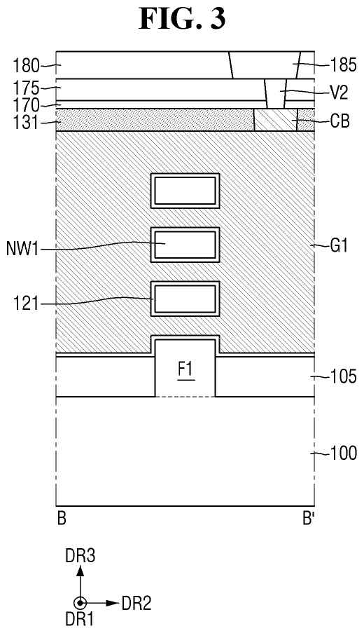

FIG. 1 is a layout view of a semiconductor device according to some embodiments of the present disclosure. FIG. 2 is a cross-sectional view taken along line A-A′ of FIG. 1. FIG. 3 is a cross-sectional view taken along line B-B′ of FIG. 1.

Referring to FIGS. 1 through 3, the semiconductor device according to some embodiments of the present disclosure may include a substrate 100, first and second active patterns F1 and F2, a field insulating layer 105, a first plurality of nanosheets NW1, a second plurality of nanosheets NW2, a third plurality of nanosheets NW3, first, second, and third gate electrodes G1, G2, and G3, first gate spacers 111, second gate spacers 112, third gate spacers 113, first, second, and third gate insulating layers 121, 122, and 123, first, second, and third gate capping patterns 131, 132, and 133, first and second source/drain regions SD1 and SD2, a first interlayer insulating layer 140, an active cut 150, a flowable material layer 160, an active cut capping pattern 134, first and second source/drain contacts CA1 and CA2, a silicide layer 145, a gate contact CB, an etch stopper layer 170, a second interlayer insulating layer 175, first vias V1, a second via V2, a third interlayer insulating layer 180, and wiring patterns 185.

The substrate 100 may be a silicon (Si) substrate or a silicon-on-insulator (SOI) substrate. Alternatively, the substrate 100 may include silicon-germanium (SiGe), silicon-germanium-on insulator (SGOI), indium antimonide, lead tellurium compound, indium arsenide, indium phosphide, gallium arsenide, or gallium antimonide, but the present disclosure is not limited thereto.

First and second horizontal directions DR1 and DR2 may be defined as directions parallel to the top surface of the substrate 100. The second horizontal direction DR2 may be defined as a different direction from the first horizontal direction DR1. A vertical direction DR3 may be defined as a direction perpendicular to the first and second horizontal directions DR1 and DR2. That is, the vertical direction DR3 may be defined as being perpendicular to the top surface of the substrate 100.

The first active pattern F1 may extend in the first horizontal direction DR1 on the substrate 100. The second active pattern F2 may extend in the first horizontal direction DR1 on the substrate 100. The second active pattern F2 may be spaced apart from the first active pattern F1 in the first horizontal direction DR1. The first and second active patterns F1 and F2 may protrude or extend from the top surface of the substrate 100 in the vertical direction DR3. For example, the first and second active patterns F1 and F2 may be parts of the substrate 100 or may include epitaxial layers grown from the substrate 100.

The field insulating layer 105 may be disposed on the top surface of the substrate 100. The field insulating layer 105 may surround the sidewalls of each of the first and second active patterns F1 and F2. For example, the top surfaces of the first and second active patterns F1 and F2 may protrude or extend beyond the top surface of the field insulating layer 105 in the vertical direction DR3, but the present disclosure is not limited thereto. Alternatively, in some embodiments, the top surfaces of the first and second active patterns F1 and F2 may be on the same plane as (e.g., may be coplanar with) the top surface of the field insulating layer 105. The field insulating layer 105 may include at least one of, for example, an oxide film, a nitride film, an oxynitride film, or a combination thereof.

The first plurality of nanosheets NW1 may be disposed on the first active pattern F1. The first plurality of nanosheets NW1 may be disposed at the intersection between the first active pattern F1 and the first gate electrode G1. The first plurality of nanosheets NW1 may include a plurality of nanosheets stacked and spaced apart from one another in the vertical direction DR3 on the first active pattern F1. The second plurality of nanosheets NW2 may be disposed on the second active pattern F2. The second plurality of nanosheets NW2 may be disposed at the intersection between the second active pattern F2 and the second gate electrode G2. The second plurality of nanosheets NW2 may include a plurality of nanosheets stacked and spaced apart from one another in the vertical direction DR3 on the second active pattern F2.

The third plurality of nanosheets NW3 may be disposed on the first and second active patterns F1 and F2. The third plurality of nanosheets NW3 may be disposed at the intersections between the third gate electrode G3 and the first and second active patterns F1 and F2. The third plurality of nanosheets NW3 may include a plurality of nanosheets stacked and spaced apart from one another in the vertical direction DR3 on the first and second active patterns F1 and F2.

FIGS. 2 and 3 illustrate that the first plurality of nanosheets NW1, the second plurality of nanosheets NW2, and the third plurality of nanosheets NW3 include stacks of three nanosheets stacked and spaced apart from one another in the vertical direction DR3, but the present disclosure is not limited thereto. Alternatively, in some embodiments, the first plurality of nanosheets NW1, the second plurality of nanosheets NW2, and the third plurality of nanosheets NW3 may include stacks of four or more nanosheets stacked and spaced apart from one another in the third direction DR3.

For example, the first plurality of nanosheets NW1, the second plurality of nanosheets NW2, and the third plurality of nanosheets NW3 may include Si, but the present disclosure is not limited thereto. Alternatively, in some embodiments, the first plurality of nanosheets NW1, the second plurality of nanosheets NW2, and the third plurality of nanosheets NW3 may include SiGe.

The first gate electrode G1 may extend in the second horizontal direction DR2 on the first active pattern F1 and the field insulating layer 105. The first gate electrode G1 may surround the first plurality of nanosheets NW1. The second gate electrode G2 may extend in the second horizontal direction DR2 on the second active pattern F2 and the field insulating layer 105. The second gate electrode G2 may be spaced apart from the first gate electrode G1 in the first horizontal direction DR1. The second gate electrode G2 may surround the second plurality of nanosheets NW2.

The third gate electrode G3 may extend in the second horizontal direction DR2 on the first and second active patterns F1 and F2 and the field insulating layer 105. The third gate electrode G3 may be disposed between the first and second gate electrodes G1 and G2. The third gate electrode G3 may be spaced apart from the first and second gate electrodes G1 and G2 in the first horizontal direction DR1. The third gate electrode G3 may surround the third plurality of nanosheets NW3.

The first, second, and third gate electrodes G1, G2, and G3 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but the present disclosure is not limited thereto. The first, second, and third gate electrodes G1, G2, and G3 may include a conductive metal oxide or a conductive metal oxynitride and may include oxidized forms of the aforementioned materials.

The first gate spacers 111 may extend in the second horizontal direction DR2 along both sidewalls of the first gate electrode G1, on the top surface of the uppermost nanosheet of the first plurality of nanosheets NW1 and the field insulating layer 105. The second gate spacers 112 may extend in the second horizontal direction DR2 along both sidewalls of the second gate electrode G2, on the top surface of the uppermost nanosheet of the second plurality of nanosheets NW2 and the field insulating layer 105. The third gate spacers 113 may extend in the second horizontal direction DR2 along both sidewalls of the third gate electrode G3, on the top surface of the uppermost nanosheet of the third plurality of nanosheets NW3 and the field insulating layer 105.

The first gate spacers 111, the second gate spacers 112, and the third gate spacers 113 may include at least one of, for example, silicon nitride (SiN), silicon oxynitride (SiON), silicon oxide (SiO₂), silicon oxycarbonitride (SiOCN), silicon boron nitride (SiBN), silicon oxyboronitride (SiOBN), or silicon oxycarbide (SiOC), but the present disclosure is not limited thereto.

The first gate insulating layer 121 may be disposed between the first gate electrode G1 and the first gate spacers 111. The first gate insulating layer 121 may be disposed on sidewalls, in the first horizontal direction DR1, of the first gate electrode G1. The first gate insulating layer 121 may be disposed between the first gate electrode G1 and the first active pattern F1. The first gate insulating layer 121 may be disposed between the first gate electrode G1 and the first plurality of nanosheets NW1.

The second gate insulating layer 122 may be disposed between the second gate electrode G2 and the second gate spacers 112. The second gate insulating layer 122 may be disposed on both sidewalls, in the first horizontal direction DR1, of the second gate electrode G2. The second gate insulating layer 122 may be disposed between the second gate electrode G2 and the second active pattern F2. The second gate insulating layer 122 may be disposed between the second gate electrode G2 and the second plurality of nanosheets NW2.

The third gate insulating layer 123 may be disposed on both sidewalls, in the first horizontal direction DR1, of the third gate electrode G3. The third gate insulating layer 123 may be disposed between the third gate electrode G3 and the first active pattern F1. The third gate insulating layer 123 may be disposed between the third gate electrode G3 and the second active pattern F2. The third gate insulating layer 123 may be disposed between the third gate electrode G3 and the third plurality of nanosheets NW3.

The first, second, and third gate insulating layers 121, 122, and 123 may include silicon oxide, silicon oxynitride, silicon nitride, or a high-k material having a greater dielectric constant than silicon oxide. The high-k material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments of the present disclosure may include a negative capacitance (NC) FET (i.e., a NC-FET) using a negative capacitor. For example, each of the first, second, and third gate insulating layers 121, 122, and 123 may include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and have positive capacitance, the total capacitance of the two or more capacitors may be lower than the individual capacitance of each of the two or more capacitors. On the contrary, if at least one of the two or more capacitors has negative capacitance, the total capacitance of the two or more capacitors may have a positive value and may be greater than the absolute value of the individual capacitance of each of the two or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film can have a sub-threshold swing (SS) of less than 60 mV/decade at room temperature.

The ferroelectric material film may have ferroelectric properties. The ferroelectric material film may include at least one of, for example, hafnium oxide, hafnium zirconium oxide, barium strontium titanium oxide, barium titanium oxide, or lead zirconium titanium oxide. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), silicon, calcium (Ca), cerium (Ce), dysprosium (Dy), erbium (Er), gadolinium (Gd), germanium, scandium (Sc), strontium (Sr), or tin (Sn). The type of dopant may vary depending on the type of material of the ferroelectric material film.

If the ferroelectric material film includes hafnium oxide, the dopant of the ferroelectric material film may include at least one of, for example, Gd, Si, Zr, Al, or Y.

If the dopant of the ferroelectric material film is Al, the ferroelectric material film may include 3 atomic % (at %) to 8 at % of Al. Here, the ratio of the dopant in the ferroelectric material film may refer to the ratio of the sum of the amounts of Hf and Al to the amount of Al in the ferroelectric material film.

If the dopant of the ferroelectric material film is Si, the ferroelectric material film may include 2 at % to 10 at % of Si. If the dopant of the ferroelectric material film is Y, the ferroelectric material film may include 2 at % to 10 at % of Y. If the dopant of the ferroelectric material film is Gd, the ferroelectric material film may include 1 at % to 7 at % of Gd. If the dopant of the ferroelectric material film is Zr, the ferroelectric material film may include 50 at % to 80 at % of Zr.

The paraelectric material film may include paraelectric properties. The paraelectric material film may include at least one of, for example, silicon oxide or a high-k metal oxide. The high-k metal oxide may include at least one of, for example, hafnium oxide, zirconium oxide, or aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. The ferroelectric material film may have a thickness of, for example, 0.5 nm to 10 nm, but the present disclosure is not limited thereto. A critical thickness that can exhibit ferroelectric properties may vary depending on the type of ferroelectric material, and thus, the thickness of the ferroelectric material film may vary depending on the type of ferroelectric material included in the ferroelectric material film.

For example, each of the first, second, and third gate insulating layers 121, 122, and 123 may include one ferroelectric material film. In another example, each of the first, second, and third gate insulating layers 121, 122, and 123 may include a plurality of ferroelectric material films that are spaced apart from one another. Each of the first, second, and third gate insulating layers 121, 122, and 123 may have a structure in which a plurality of ferroelectric material films and a plurality of paraelectric material films are alternately stacked.

The first gate capping patterns 131 may extend in the second horizontal direction DR2 on the first gate spacers 111, the first gate insulating layer 121, and the first gate electrode G1. The second gate capping pattern 132 may extend in the second horizontal direction DR2 on the second gate spacers 112, the second gate insulating layer 122, and the second gate electrode G2. The third gate capping pattern 133 may extend in the second horizontal direction DR2 on the third gate spacers 113. The first, second, and third gate capping patterns 131, 132, and 133 may include at least one of, for example, SiN, SiON, SiO₂, SiCN, SiOCN, or a combination thereof, but the present disclosure is not limited thereto.

The first source/drain region SD1 may be disposed on at least one side, in the first horizontal direction DR1, of the first gate electrode G1, on the first active pattern F1. For example, the first source/drain region SD1 may be disposed on both sides, in the first horizontal direction DR1, of the first gate electrode G1, on the first active pattern F1. The first source/drain region SD1 may be in contact with the first plurality of nanosheets NW1 and the third plurality of nanosheets NW3.

The second source/drain region SD2 may be disposed on at least one side, in the first horizontal direction DR1, of the second gate electrode G2, on the second active pattern F2. For example, the second source/drain region SD2 may be disposed on both sides, in the first horizontal direction DR1, of the second gate electrode G2, on the second active pattern F2. The second source/drain region SD2 may be in contact with the second plurality of nanosheets NW2 and the third plurality of nanosheets NW3.

FIG. 2 illustrates that the first source/drain region SD1 is in contact with the first and third gate insulating layers 121 and 123 and the second source/drain region SD2 is in contact with the second and third gate insulating layers 122 and 123, but the present disclosure is not limited thereto. Alternatively, in some embodiments, inner spacers may be disposed between the first source/drain region SD1 and the first gate insulating layer 121 and between the first source/drain region SD1 and the third gate insulating layer 123, and inner spacers may be disposed between the second source/drain region SD2 and the second gate insulating layer 122 and between the second source/drain region SD2 and the third gate insulating layer 123.

A first trench T1 may extend in the second horizontal direction DR2 between the first and second gate electrodes G1 and G2. The first trench T1 may extend into the substrate 100 by penetrating or extending into the third gate capping pattern 133, the third gate electrode G3, the third gate insulating layer 123, and the third plurality of nanosheets NW3 in the vertical direction DR3. That is, part of the first trench T1 may be formed in the substrate 100. For example, part of the first trench T1 may extend in the substrate 100. The first trench T1 may separate the first and second active patterns F1 and F2.

The active cut 150 may extend in the second horizontal direction DR2 in the first trench T1. For example, the active cut 150 may be disposed along the sidewalls and the bottom surface of the first trench T1. That is, the active cut 150 may be disposed between the first and second gate electrodes G1 and G2. The active cut 150 may be spaced apart from the first and second gate electrodes G1 and G2 in the first horizontal direction DR1. At least part of the active cut 150 may be disposed in or extend in the substrate 100.

For example, the top surface of the active cut 150 may be formed on the same plane as (e.g., may be coplanar with) the top surfaces of the first, second, and third gate capping patterns 131, 132, and 133, but the present disclosure is not limited thereto. Alternatively, in some embodiments, the top surface of the active cut 150 may be formed to be higher than the top surfaces of the first, second, and third gate capping patterns 131, 132, and 133 relative to the substrate 100.

The sidewalls of the active cut 150 may be in contact with the first and second active patterns F1 and F2. The sidewalls of the active cut 150 may be in contact with the third gate spacers 113, the third gate insulating layer 123, the third gate capping pattern 133, the third gate electrode G3, and the third plurality of nanosheets NW3, but the present disclosure is not limited thereto. Alternatively, in some embodiments, the third gate insulating layer 123 may be disposed between the active cut 150 and the third gate spacers 113.

For example, the active cut 150 may include the same material as the first, second, and third gate capping patterns 131, 132, and 133, but the present disclosure is not limited thereto. Alternatively, in some embodiments, the active cut 150 may include a material different from that of the first, second, and third gate capping patterns 131, 132, and 133. The active cut 150 may include one of, for example, SiN, SiON, SiO₂, SiOCN, or a combination thereof, but the present disclosure is not limited thereto.

A second trench T2 may be formed on the active cut 150, in the first trench T1. That is, the second trench T2 may be defined by the inner sidewalls of the active cut 150, in the first trench T1. For example, at least part of the second trench T2 may be formed in or extend in the substrate 100, but the present disclosure is not limited thereto.

The flowable material layer 160 may be disposed in the second trench T2. That is, the flowable material layer 160 may be defined as being disposed in the active cut 150. At least part of the flowable material layer 160 may be formed in or extend in the substrate 100, but the present disclosure is not limited thereto.

The flowable material layer 160 may fill or be in at least part of the second trench T2. For example, the sidewalls and the bottom surface of the flowable material layer 160 may be in contact with the active cut 150. For example, a top surface 160a of the flowable material layer 160 may be formed to be lower than the top surface of the active cut 150 relative to the substrate 100. The top surface 160a of the flowable material layer 160 may be formed to be higher than the top surfaces of the uppermost ones of the first, second, and third plurality of nanosheets NW1, NW2, and NW3 relative to the substrate 100. For example, the flowable material layer 160 may not be in contact with the substrate 100, the first active pattern F1, and the second active pattern F2.

The flowable material layer 160 may include a material different from that of the active cut 150 and the first, second, and third gate capping patterns 131, 132, and 133. The flowable material layer 160 may include a flowable insulating material. In some embodiments, the flowable material layer 160 may include a material having the same tensile stress as the first interlayer insulating layer 140. Alternatively, in some embodiments, the flowable material layer 160 may include a material having compressive stress. The flowable material layer 160 may include one of, for example, tonen silazen (TOSZ), flowable low-k (FLK), or flowable silicon carbide (FSiC).

The active cut capping pattern 134 may be disposed in the second trench T2. That is, the active cut capping pattern 134 may be defined as being disposed in the active cut 150. The active cut capping pattern 134 may be disposed on the top surface 160a of the flowable material layer 160, in the second trench T2. For example, the bottom surface of the active cut capping pattern 134 may be in contact with the top surface 160a of the flowable material layer 160, but the present disclosure is not limited thereto. The sidewalls of the active cut capping pattern 134 may be in contact with the active cut 150. For example, the region in which the flowable material layer 160 is formed may be sealed by the active cut 150 and the active cut capping pattern 134. As a result, the flowable material layer 160 can be prevented from moving out of the active cut 150.

For example, the top surface of the active cut capping pattern 134 may be formed on the same plane as (e.g., may be coplanar with) the top surface of the active cut 150. For example, the top surface of the active cut capping pattern 134 may be formed on the same plane as (e.g., may be coplanar with) the top surfaces of the first, second, and third gate capping patterns 131, 132, and 133, but the present disclosure is not limited thereto. For example, the bottom surface of the active cut capping pattern 134 may be formed to be lower than the bottom surfaces of the first, second, and third gate capping patterns 131, 132, and 133 relative to the substrate 100.

The active cut capping pattern 134 may include a material different from that of the flowable material layer 160. For example, the active cut capping pattern 134 may include the same material as the first, second, and third gate capping patterns 131, 132, and 133, but the present disclosure is not limited thereto. Also, for example, the active cut capping pattern 134 may include the same material as the active cut 150, but the present disclosure is not limited thereto. The active cut capping pattern 134 may include at least one of, for example, SiN, SiON, SiO₂, SiOCN, or a combination thereof, but the present disclosure is not limited thereto.

The first interlayer insulating layer 140 may be disposed on the field insulating layer 105. The first interlayer insulating layer 140 may cover, overlap, or be on the first and second source/drain regions SD1 and SD2. The first interlayer insulating layer 140 may surround the sidewalls of each of the first gate spacers 111, the sidewalls of each of the second gate spacers 112, the sidewalls of each of the third gate spacers 113, the sidewalls of the first gate capping pattern 131, the sidewalls of the second gate capping pattern 132, and the sidewalls of the third gate capping pattern 133. For example, the top surface of the first interlayer insulating layer 140 may be formed on the same plane as (e.g., may be coplanar with) the top surfaces of the first, second, and third gate capping patterns 131, 132, and 133 and the top surface of the active cut capping pattern 134.

The first interlayer insulating layer 140 may include at least one of, for example, silicon oxide, silicon nitride, silicon oxynitride, or a low-k material. The low-k material may include, for example, fluorinated tetraethyl orthosilicate (FTEOS), hydrogen silsesquioxane (HSQ), bis-benzocyclobutene (BCB), tetramethyl orthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), TOSZ, fluoride silicate glass (FSG), polyimide nanofoam (such as polypropylene oxide), carbon doped silicon oxide (CDO), organo silicate glass (OSG), SiLK, amorphous fluorinated carbon, silica aerogel, silica xerogel, mesoporous silica, or a combination thereof, but the present disclosure is not limited thereto.

The first source/drain contact CA1 may be disposed between the first gate electrode G1 and the active cut 150. The first source/drain contact CA1 may penetrate or extend into the first interlayer insulating layer 140 in the vertical direction DR3 to be connected to the first source/drain region SD1. The second source/drain contact CA2 may be disposed between the active cut 150 and the second gate electrode G2. The second source/drain contact CA2 may penetrate or extend into the first interlayer insulating layer 140 in the vertical direction DR3 to be connected to the second source/drain region SD2.

For example, the top surfaces of the first and second source/drain contacts CA1 and CA2 may be formed on the same plane as (e.g., may be coplanar with) the top surface of the first interlayer insulating layer 140. FIG. 2 illustrates that the first and second source/drain contacts CA1 and CA2 are formed as single films, but the present disclosure is not limited thereto. That is, alternatively, the first and second source/drain contacts CA1 and CA2 may be formed as multifilms. The first and second source/drain contacts CA1 and CA2 may include a conductive material.

The silicide layer 145 may be disposed between the first source/drain contact CA1 and the first source/drain region SD1. Also, the silicide layer 145 may be disposed between the second source/drain contact CA2 and the second source/drain region SD2. The silicide layer 145 may include, for example, a metal silicide material.

For example, the gate contact CB may penetrate or extend into the first gate capping pattern 131 in the vertical direction DR3 to be connected to the first gate electrode G1. For example, the top surface of the gate contact CB may be formed on the same plane as (e.g., may be coplanar with) the top surface of the first interlayer insulating layer 140. FIG. 3 illustrates that the gate contact CB is formed as a single film, but the present disclosure is not limited thereto. That is, alternatively, the gate contact CB may be formed as a multifilm. The gate contact CB may include a conductive material.

For example, the etch stopper layer 170 may be disposed on the top surfaces of the first interlayer insulating layer 140, the first, second, and third gate capping patterns 131, 132, and 133, the active cut capping pattern 134, the active cut 150, the first and second source/drain contacts CA1 and CA2, and the gate contact CB. FIGS. 2 and 3 illustrate that the etch stopper layer 170 is formed as a single film, but the present disclosure is not limited thereto. Alternatively, in some embodiments, the etch stopper layer 170 may be formed as a multifilm. The etch stopper layer 170 may include at least one of, for example, aluminum oxide, aluminum nitride, hafnium oxide, zirconium oxide, silicon oxide, silicon nitride, silicon oxynitride, or a low-k material. The second interlayer insulating layer 175 may be disposed on the etch stopper layer 170. The second interlayer insulating layer 175 may include at least one of, for example, silicon oxide, silicon nitride, silicon oxynitride, or a low-k material.

The first vias V1 may penetrate or extend into the second interlayer insulating layer 175 and the etch stopper layer 170 in the vertical direction DR3 and may thus be connected to the first and second source/drain contacts CA1 and CA2. The second via V2 may penetrate or extend into the second interlayer insulating layer 175 and the etch stopper layer 170 in the vertical direction DR3 and may thus be connected to the gate contact CB. FIGS. 2 and 3 illustrate that the first vias V1 and the second via V2 are formed as single films, but the present disclosure is not limited thereto. Alternatively, the first vias V1 and the second via V2 may be formed as multifilms. The first vias V1 and the second via V2 may include a conductive material.

The third interlayer insulating layer 180 may be disposed on the second interlayer insulating layer 175. The third interlayer insulating layer 180 may include at least one of, for example, silicon oxide, silicon nitride, silicon oxynitride, or a low-k material. The wiring patterns 185 may be disposed in the third interlayer insulating layer 180. The wiring patterns 185 may be connected to the first vias V1 or the second via V2. FIGS. 2 and 3 illustrate that the wiring patterns 185 are formed as single films, but the present disclosure is not limited thereto. Alternatively, the wiring patterns 185 may be formed as multifilms. The wiring patterns 185 may include a conductive material.

The inside of the active cut 150 may be filled with a flowable insulating material including a material having the same tensile or compressive stress as the first interlayer insulating layer 140. Accordingly, the expansion of the active cut 150 in the first horizontal direction DR1 can be prevented, and as a result, defects in the source/drain contacts CA1 and CA2 can be prevented.

A method of fabricating a semiconductor device according to some embodiments of the present disclosure will hereinafter be described with reference to FIGS. 2 through 21.

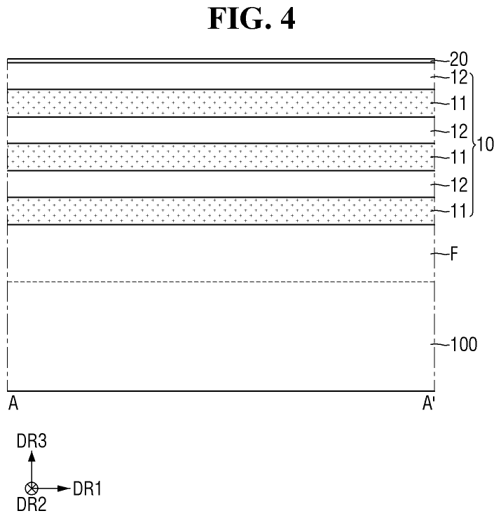

FIGS. 4 through 21 are cross-sectional views illustrating intermediate steps of a method of fabricating a semiconductor device according to some embodiments of the present disclosure.

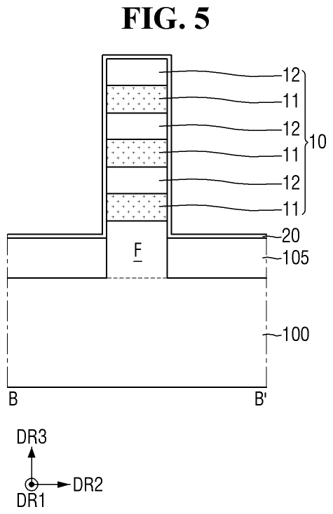

Referring to FIGS. 4 and 5, a stack structure 10 may be formed on the top surface of a substrate 100. The stack structure 10 may include first semiconductor layers 11 and second semiconductor layers 12, and the first semiconductor layers 11 and the second semiconductor layers 12 may be alternately stacked on the substrate 100. For example, one of the first semiconductor layers 11 may be formed as a lowermost layer of the stack structure 10, and one of the second semiconductor layers 12 may be formed as an uppermost layer of the stack structure 10. However, the present disclosure is not limited to this example. In another example, a first semiconductor layer 11 may be formed as the uppermost layer of the stack structure 10. The first semiconductor layers 11 may include, for example, SiGe. The second semiconductor layers 12 may include, for example, Si.

Thereafter, the stack structure 10 may be partially etched. While the stack structure 10 is being etched, the substrate 100 may also be partially etched. As a result, an active pattern F may be defined on the substrate 100, below the stack structure 10. The active pattern F may extend in a first horizontal direction DR1. Thereafter, a field insulating layer 105 may be formed on the substrate 100. The field insulating layer 105 may surround the sidewalls of the active patterns F. For example, the top surface of the active pattern F may be formed to be higher than the top surface of the field insulating layer 105 relative to the substrate 100. Thereafter, a pad oxide layer 20 may be formed to cover, overlap, or be on the top surface of the field insulating layer 105, exposed parts of the sidewalls of the active pattern F, and the sidewalls and the top surface of the stack structure 10. For example, the pad oxide layer 20 may be conformally formed. The pad oxide layer 20 may include, for example, SiO₂.

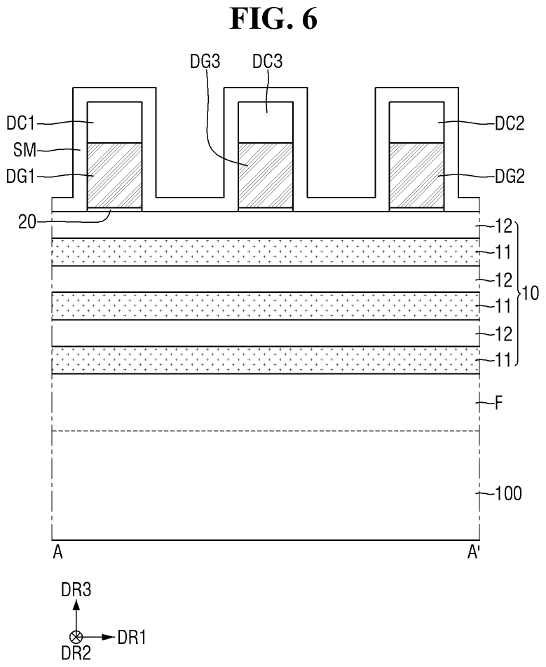

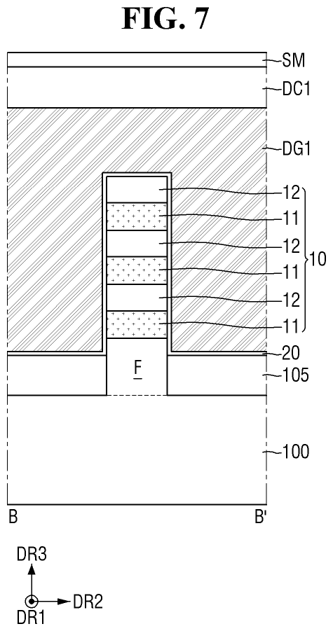

Referring to FIGS. 6 and 7, first, second, and third dummy gates DG1, DG2, and DG3 and first, second, and third capping patterns DC1, DC2, and DC3 may be formed on the stack structure 10 and the field insulating layer 105 to extend in a second horizontal direction DR2 on the pad oxide layer 20. For example, the third dummy gate DG3 may be spaced apart from the first dummy gate DG1 in the first horizontal direction DR1, and the second dummy gate DG2 may be spaced apart from the third dummy gate DG3 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3.

During the formation of the first, second, and third dummy gates DG1, DG2, and DG3 and the first, second, and third capping patterns DC1, DC2, and DC3, the entire pad oxide layer 20 except for parts overlapping with the first, second, and third dummy gates DG1, DG2, and DG3 in a vertical direction DR3 may be removed from above the substrate 100.

Thereafter, a spacer material layer SM may be formed to cover, overlap, or be on the sidewalls of each of the first, second, and third dummy gates DG1, DG2, and DG3, the sidewalls and the top surface of each of the first, second, and third capping patterns DC1, DC2, and DC3, exposed parts of the sidewalls and the top surface of the stack structure 10, and the top surface of the field insulating layer 105. For example, the spacer material layer SM may be conformally formed. The spacer material layer SM may include at least one of, for example, SiN, SiOCN, silicon boron carbonitride (SiBCN), SiCN, SiON, or a combination thereof.

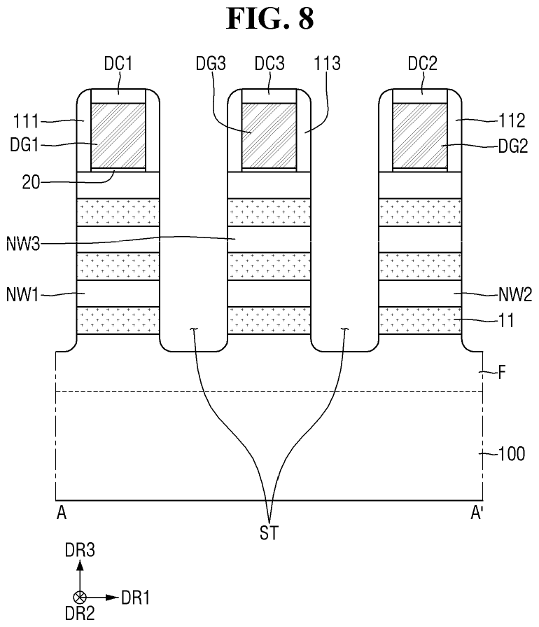

Referring to FIG. 8, source/drain trenches ST may be formed by etching the stack structure 10 of FIG. 6 using the first, second, and third dummy gates DG1, DG2, and DG3 and the first, second, and third capping patterns DC1, DC2, and DC3 as a mask. For example, the source/drain trenches ST may extend into the active pattern F. During the formation of the source/drain trenches ST, parts of the first, second, and third capping patterns DC1, DC2, and DC3 and parts of the spacer material layer SM on the top surfaces of the first, second, and third capping patterns DC1, DC2, and DC3 may be etched.

For example, parts of the spacer material layer SM that remain on the sidewalls of each of the first, second, and third capping patterns DC1, DC2, and DC3 and the sidewalls of each of the first, second, and third dummy gates DG1, DG2, and DG3 may be defined as first gate spacers 111, second gate spacers 112, and third gate spacers 113. For example, after the formation of the source/drain trenches ST, parts of the second semiconductor layers 12 that remain below the first dummy gate DG1, parts of the second semiconductor layers 12 that remain below the second dummy gate DG2, and parts of the second semiconductor layers 12 that remain below the third dummy gate DG3 may be defined as a first plurality of nanosheets NW1, a second plurality of nanosheets NW2, and a third plurality of nanosheets NW3, respectively.

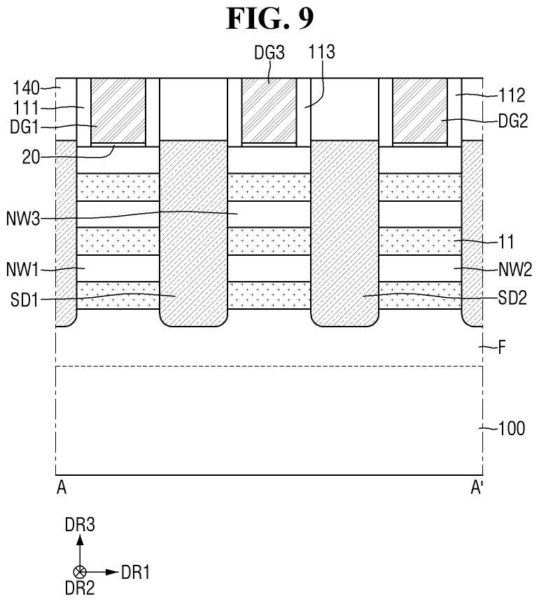

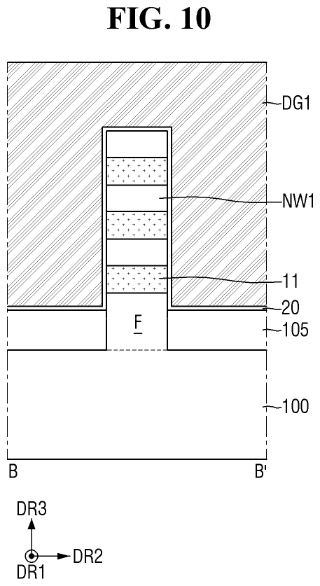

Referring to FIGS. 9 and 10, first and second source/drain regions SD1 and SD2 may be formed in the source/drain trenches ST, which are formed on the active pattern F. For example, the first source/drain region SD1 may be formed between the first plurality of nanosheets NW1 and the third plurality of nanosheets NW3, and the second source/drain region SD2 may be formed between the second plurality of nanosheets NW2 and the third plurality of nanosheets NW3.

Thereafter, a first interlayer insulating layer 140 may be formed to cover, overlap, or be on the sidewalls and the top surface of each of the first and second source/drain regions SD1 and SD2 and to cover, overlap, or be on the first gate spacers 111, the second gate spacers 112, the third gate spacers 113, and the first, second, and third dummy capping patterns DC1, DC2, and DC3. Thereafter, the top surfaces of the first, second, and third dummy gates DG1, DG2, and DG3 may be exposed by a planarization process.

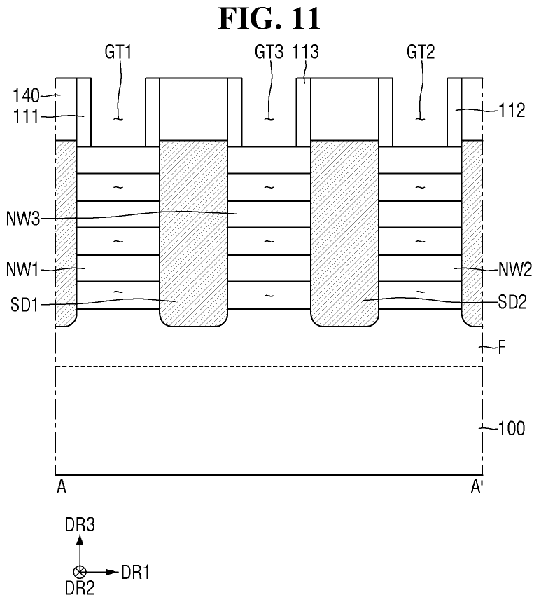

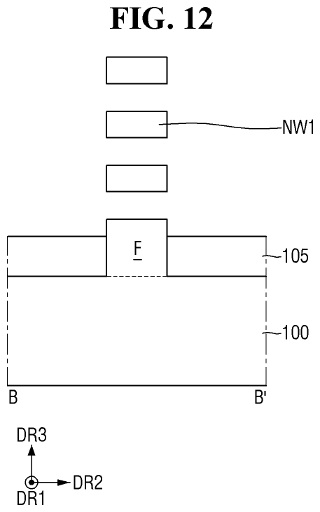

Referring to FIGS. 11 and 12, the first, second, and third dummy gates DG1, DG2, and DG3, the pad oxide layer 20, and the first semiconductor layers 11 of FIG. 9 may be etched away. A region from which the first dummy gate DG1 is removed may be defined as a first gate trench GT1. A region from which the second dummy gate DG2 is removed may be defined as a second gate trench GT2. A region from which the third dummy gate DG3 is removed may be defined as a third gate trench GT3.

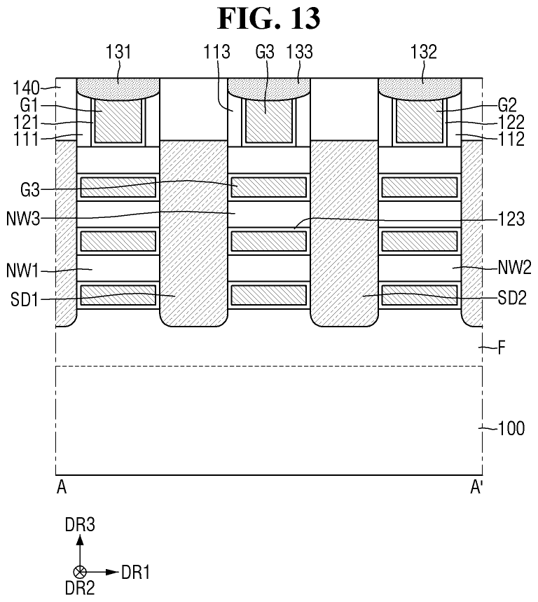

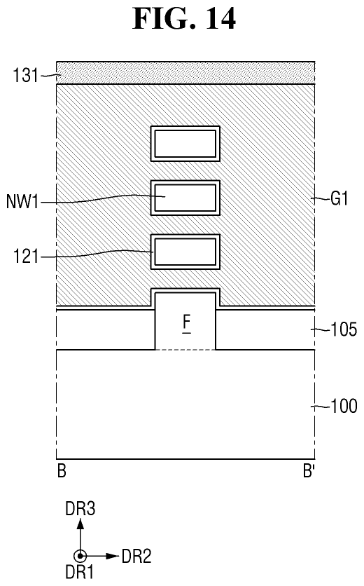

Referring to FIGS. 13 and 14, a first gate insulating layer 121, a first gate electrode G1, and a first gate capping pattern 131 may be sequentially formed in the first gate trench GT1 of FIG. 11. A second gate insulating layer 122, a second gate electrode G2, and a second gate capping pattern 132 may be sequentially formed in the second gate trench GT2 of FIG. 11. A third gate insulating layer 123, a third gate electrode G3, and a third gate capping pattern 133 may be sequentially formed in the third gate trench GT3 of FIG. 11.

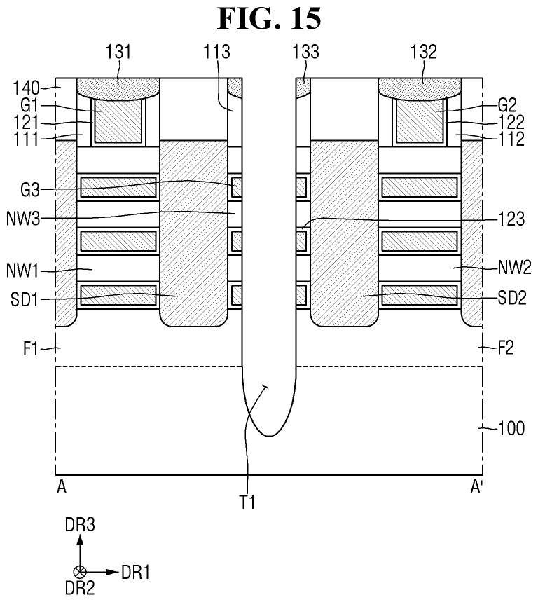

Referring to FIG. 15, a first trench T1, which extends in the second horizontal direction DR2, may be formed between the first and second gate electrodes G1 and G2. The first trench T1 may penetrate or extend into the third gate capping pattern 133, the third gate electrode G3, the third gate insulating layer 123, and the third plurality of nanosheets NW3 in the vertical direction DR3 to extend into the substrate 100.

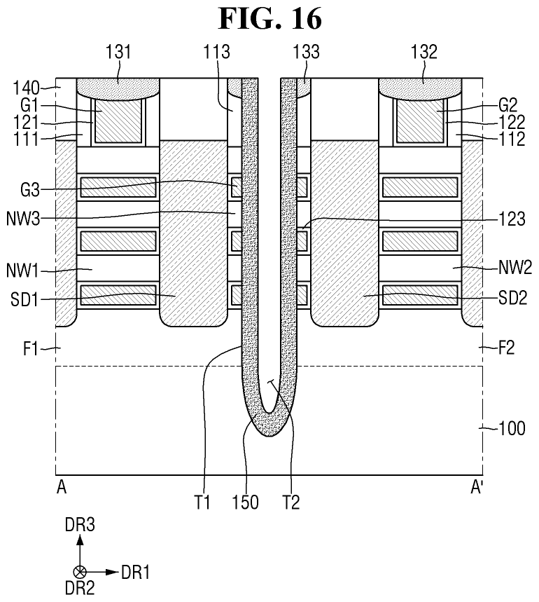

Referring to FIG. 16, an active cut 150 may be formed along the sidewalls and the bottom surface of the first trench T1. For example, the active cut 150 may be conformally formed. After the formation of the active cut 150, a second trench T2 may be defined on the active cut 150, in the first trench T1.

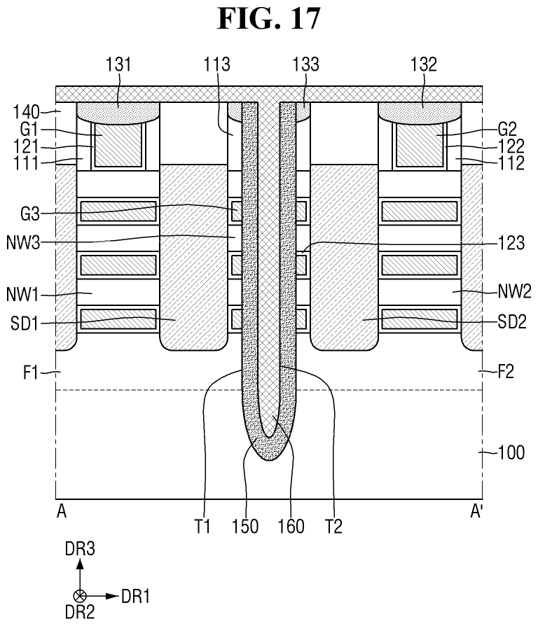

Referring to FIG. 17, the second trench T2 may be filled with a flowable material layer 160, which includes a flowable insulating material. For example, the flowable material layer 160 may also be formed on the top surfaces of the first interlayer insulating layer 140 and the first, second, and third gate capping patterns 131, 132, and 133.

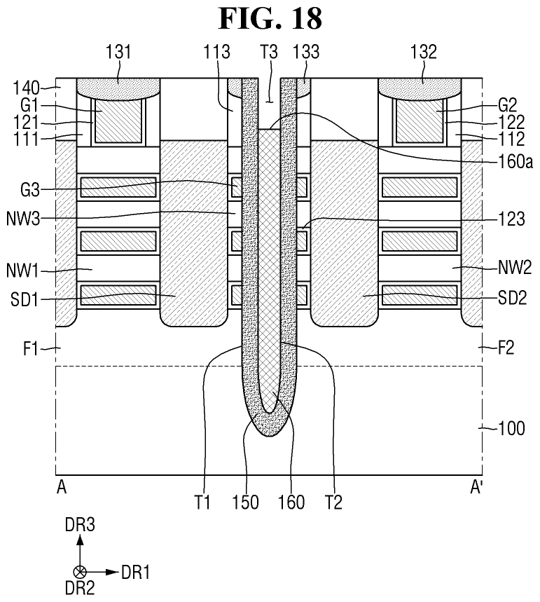

Referring to FIG. 18, the flowable material layer 160 may be partially etched. For example, parts of the flowable material layer 160 on the top surfaces of the first interlayer insulating layer 140 and the first, second, and third gate capping patterns 131, 132, and 133 may be etched. Also, part of the flowable material layer 160 in the second trench T2 may be etched. As a result, a top surface 160a of the flowable material layer 160 in the second trench T2 may be formed to be lower than the top surface of the active cut 150 relative to the substrate 100. After the etching of the flowable material layer 160, a third trench T3 may be defined on the top surface 160a of the flowable material layer 160, in the second trench T2.

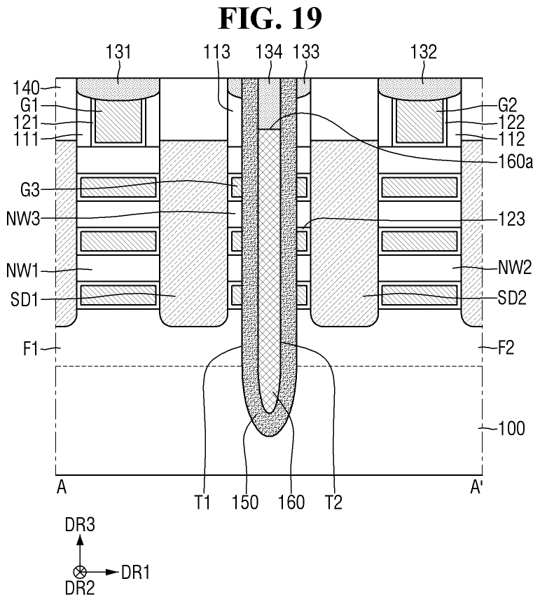

Referring to FIG. 19, an active cut capping pattern 134 may be formed in the third trench T3. For example, the top surface of the active cut capping pattern 134 may be formed on the same plane as (e.g., may be coplanar with) the top surfaces of the first, second, and third gate capping patterns 131, 132, and 133. Also, for example, the bottom surface of the active cut capping pattern 134 may be formed to be lower than the bottom surfaces of the first, second, and third gate capping patterns 131, 132, and 133 relative to the substrate 100.

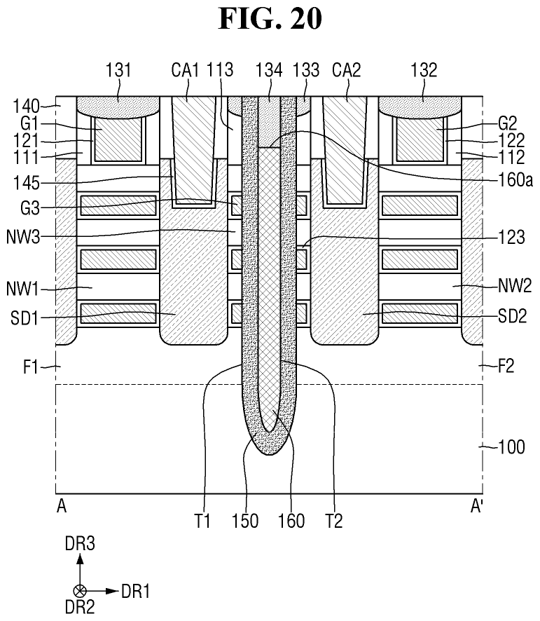

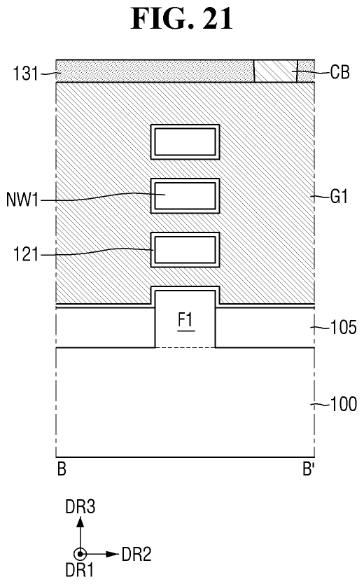

Referring to FIGS. 20 and 21, a first source/drain contact CA1, which penetrates or extends into the first interlayer insulating layer 140 in the vertical direction DR3, between the first gate electrode G1 and the active cut 150, to be connected to the first source/drain region SD1, may be formed. Also, a second source/drain contact CA2, which penetrates or extends into the first interlayer insulating layer 140 in the vertical direction DR3, between the active cut 150 and the second gate electrode G2, to be connected to the second source/drain region SD2, may be formed. Also, a gate contact CB, which penetrates or extends into the first gate capping pattern 131 in the vertical direction DR3 to be connected to the first gate electrode G1, may be formed. Also, a silicide layer 145 may be formed between the first source/drain region SD1 and the first source/drain contact CA1 and between the second source/drain region SD2 and the second source/drain contact CA2.

Referring to FIGS. 2 and 3, an etch stopper layer 170 and a second interlayer insulating layer 175 may be sequentially formed on the top surfaces of the first interlayer insulating layer 140, the first, second, and third gate capping patterns 131, 132, and 133, the active cut capping pattern 134, the active cut 150, the first and second source/drain contacts CA1 and CA2, and the gate contact CB.

Thereafter, first vias V1, which penetrate or extend into the second interlayer insulating layer 175 and the etch stopper layer 170 in the vertical direction DR3 to be connected to the first and second source/drain contacts CA1 and CA2, may be formed. Also, a second via V2, which penetrates or extends into the second interlayer insulating layer 175 and the etch stopper layer 170 in the vertical direction DR3 to be connected to the gate contact CB, may be formed. Thereafter, a third interlayer insulating layer 180 and wiring patterns 185 may be formed on the second interlayer insulating layer 175. In this manner, the semiconductor device of FIGS. 2 and 3 can be obtained.

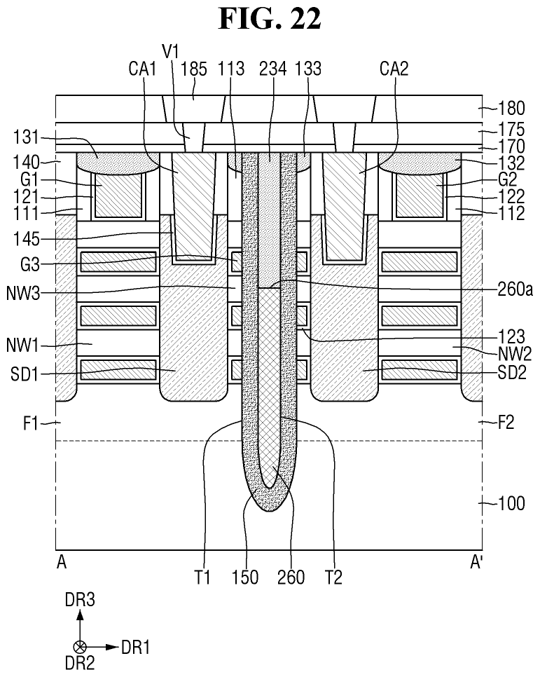

A semiconductor device according to some embodiments of the present disclosure will hereinafter be described with reference to FIG. 22, focusing mainly on the differences with the semiconductor device of FIGS. 1 through 3.

FIG. 22 is a cross-sectional view of a semiconductor device according to some embodiments of the present disclosure.

Referring to FIG. 22, a top surface 260a of a flowable material layer 260 may be formed to be lower than the top surfaces of uppermost ones of the first, second, and third plurality of nanosheets NW1, NW2, and NW3 relative to the substrate 100.

For example, the top surface 260a of the flowable material layer 260 may be formed to be higher than the bottom surfaces of lowermost ones of the first, second, and third plurality of nanosheets NW1, NW2, and NW3 relative to the substrate 100. That is, the top surface 260a of the flowable material layer 260 may be formed between the bottom surfaces of the lowermost ones of the first, second, and third plurality of nanosheets NW1, NW2, and NW3 and the top surfaces of the uppermost ones of the first, second, and third plurality of nanosheets NW1, NW2, and NW3.

For example, the bottom surface of an active cut capping pattern 234 may be in contact with the top surface 260a of the flowable material layer 260. The bottom surface of the active cut capping pattern 234 may be formed between the bottom surfaces of the lowermost ones of the first, second, and third plurality of nanosheets NW1, NW2, and NW3 and the top surfaces of the uppermost ones of the first, second, and third plurality of nanosheets NW1, NW2, and NW3.

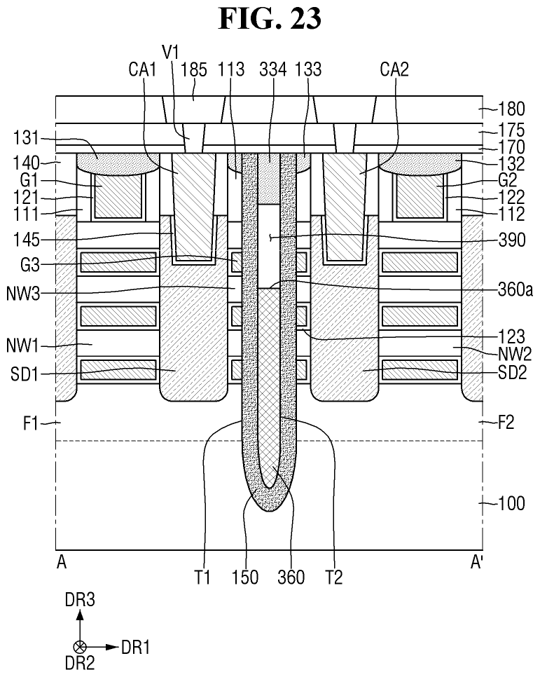

A semiconductor device according to some embodiments of the present disclosure will hereinafter be described with reference to FIG. 23, focusing mainly on the differences with the semiconductor device of FIGS. 1 through 3.

FIG. 23 is a cross-sectional view of a semiconductor device according to some embodiments of the present disclosure.

Referring to FIG. 23, an airgap 390 may be formed between a top surface 360a of a flowable material layer 360 and the bottom surface of an active cut capping pattern 334, in a second trench T2.

For example, the top surface 360a of the flowable material layer 360 may be formed between the bottom surfaces of lowermost ones of the first, second, and third plurality of nanosheets NW1, NW2, and NW3 and the top surfaces of uppermost ones of the first, second, and third plurality of nanosheets NW1, NW2, and NW3. For example, the bottom surface of the active cut capping pattern 334 may be formed to be higher than the top surfaces of the uppermost ones of the first, second, and third plurality of nanosheets NW1, NW2, and NW3 relative to the substrate 100.

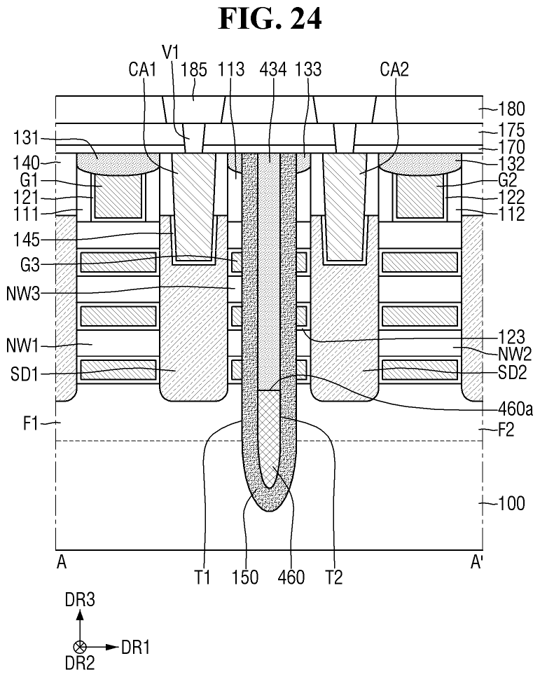

A semiconductor device according to some embodiments of the present disclosure will hereinafter be described with reference to FIG. 24, focusing mainly on the differences with the semiconductor device of FIGS. 1 through 3.

FIG. 24 is a cross-sectional view of a semiconductor device according to some embodiments of the present disclosure.

Referring to FIG. 24, a top surface 460a of a flowable material layer 460 may be formed to be lower than the bottom surfaces of lowermost ones of the first, second, and third plurality of nanosheets NW1, NW2, and NW3 relative to the substrate 100.

For example, the bottom surface of an active cut capping pattern 434 may be in contact with the top surface 460a of the flowable material layer 460. The bottom surface of the active cut capping pattern 434 may be formed to be lower than the bottom surfaces of the lowermost ones of the first, second, and third plurality of nanosheets NW1, NW2, and NW3 relative to the substrate 100.

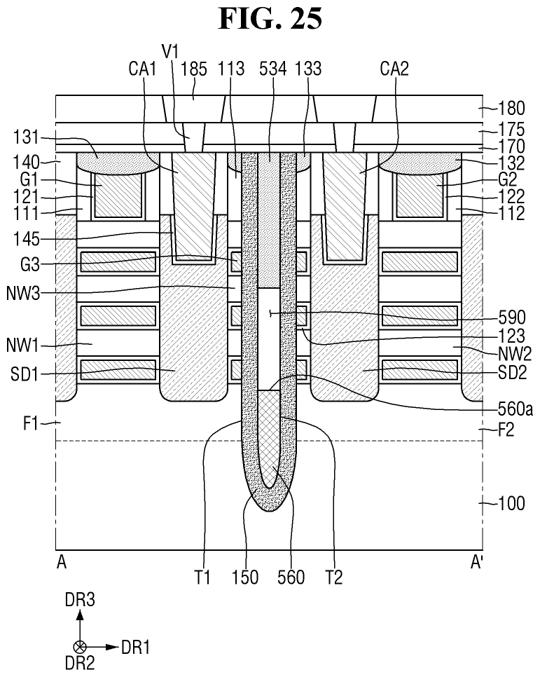

A semiconductor device according to some embodiments of the present disclosure will hereinafter be described with reference to FIG. 25, focusing mainly on the differences with the semiconductor device of FIGS. 1 through 3.

FIG. 25 is a cross-sectional view of a semiconductor device according to some embodiments of the present disclosure.

Referring to FIG. 25, an airgap 590 may be formed between a top surface 560a of a flowable material layer 560 and the bottom surface of an active cut capping pattern 534, in a second trench T2.

For example, the top surface 560a of the flowable material layer 560 may be formed to be lower than the bottom surfaces of lowermost ones of the first, second, and third plurality of nanosheets NW1, NW2, and NW3 relative to the substrate 100. For example, the bottom surface of the active cut capping pattern 534 may be formed between the bottom surfaces of the lowermost ones of the first, second, and third plurality of nanosheets NW1, NW2, and NW3 and the top surfaces of uppermost ones of the first, second, and third plurality of nanosheets NW1, NW2, and NW3.

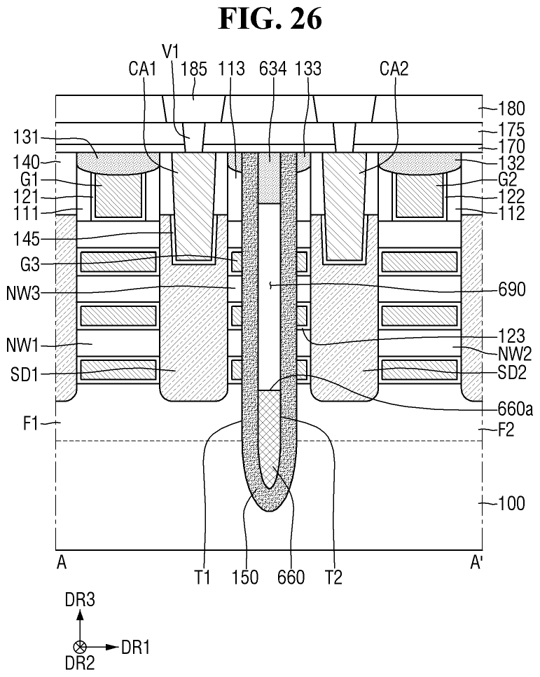

A semiconductor device according to some embodiments of the present disclosure will hereinafter be described with reference to FIG. 26, focusing mainly on the differences with the semiconductor device of FIGS. 1 through 3.

FIG. 26 is a cross-sectional view of a semiconductor device according to some embodiments of the present disclosure.

Referring to FIG. 26, an airgap 690 may be formed between a top surface 660a of a flowable material layer 660 and the bottom surface of an active cut capping pattern 634, in a second trench T2.

For example, the top surface 660a of the flowable material layer 660 may be formed to be lower than the bottom surfaces of the lowermost ones of the first, second, and third plurality of nanosheets NW1, NW2, and NW3 relative to the substrate 100. For example, the bottom surface of the active cut capping pattern 634 may be formed to be higher than the top surfaces of uppermost ones of the first, second, and third plurality of nanosheets NW1, NW2, and NW3 relative to the substrate 100.

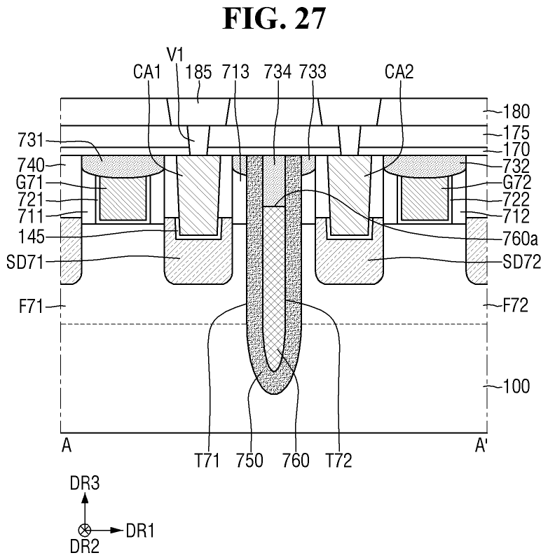

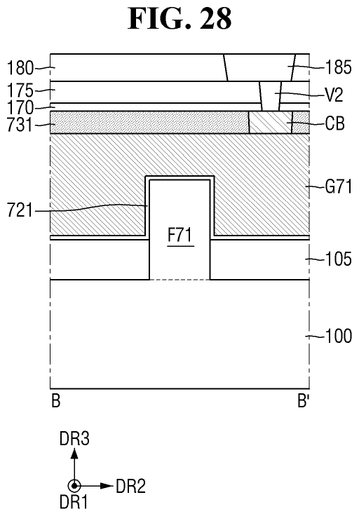

A semiconductor device according to some embodiments of the present disclosure will hereinafter be described with reference to FIGS. 27 and 28, focusing mainly on the differences with the semiconductor device of FIGS. 1 through 3.

FIGS. 27 and 28 are cross-sectional views of a semiconductor device according to some embodiments of the present disclosure.

Referring to FIGS. 27 and 28, the semiconductor device according to some embodiments of the present disclosure may include a FinFET. For example, the semiconductor device according to some embodiments of the present disclosure may include a substrate 100, first and second active patterns F71 and F72, a field insulating layer 105, first and second gate electrodes G71 and G72, first gate spacers 711, second gate spacers 712, third gate spacers 713, first and second gate insulating layers 721 and 722, first, second, and third gate capping patterns 731, 732, and 733, first and second source/drain regions SD71 and SD72, a first interlayer insulating layer 740, an active cut 750, a flowable material layer 760, an active cut capping pattern 734, first and second source/drain contacts CA1 and CA2, a silicide layer 145, a gate contact CB, an etch stopper layer 170, a second interlayer insulating layer 175, first vias V1, a second via V2, a third interlayer insulating layer 180, and wiring patterns 185. Descriptions of features or elements that have already been described above with reference to FIGS. 1 through 3 will be omitted.

The first and second active patterns F71 and F72 may extend in a first horizontal direction DR1 on a substrate 100. The second active pattern F72 may be spaced apart from the first active pattern F71 in the first horizontal direction DR1. The first gate electrode G71 may extend in a second horizontal direction DR2 on the first active pattern F71 and the field insulating layer 105. The second gate electrode G72 may extend in the second horizontal direction DR2 on the second active pattern F72 and the field insulating layer 105.

The first gate spacers 711 may extend in the second horizontal direction DR2 along both sidewalls of the first gate electrode G71, on the first active pattern F71. The second gate spacers 712 may extend in the second horizontal direction DR2 along both sidewalls of the second gate electrode G72, on the second active pattern F72. The third gate spacers 713 may extend in the second horizontal direction DR2 along both sidewalls of the active cut 750 on the first and second active patterns F71 and F72.

The first gate insulating layer 721 may be disposed between the first gate electrode G71 and the first active pattern F71. The first gate insulating layer 721 may be disposed between the first gate electrode G71 and the first gate spacers 711. The second gate insulating layer 722 may be disposed between the second gate electrode G72 and the second active pattern F72. The second gate insulating layer 722 may be disposed between the second gate electrode G72 and the second gate spacers 712.

The first gate capping pattern 731 may extend in the second horizontal direction DR2 on the first gate spacers 711, the first gate insulating layer 721, and the first gate electrode G71. The second gate capping pattern 732 may extend in the second horizontal direction DR2 on the second gate spacers 712, the second gate insulating layer 722, and the second gate electrode G72. The third gate capping pattern 733 may extend in the second horizontal direction DR2 on the third gate spacers 713.

The first source/drain region SD71 may be disposed on both sides, in the first horizontal direction DR1, of the first gate electrode G71, on the first active pattern F71. The second source/drain region SD72 may be disposed on both sides, in the first horizontal direction DR1, of the second gate electrode G72, on the second active pattern F72. The first trench T71 may extend in the second horizontal direction DR2 between the first and second gate electrodes G71 and G72. The first trench T71 may penetrate or extend into the third gate capping pattern 733 in a vertical direction DR3 to extend into the substrate 100. The first trench T71 may separate the first and second active patterns F71 and F72.

The active cut 750 may extend in the second horizontal direction DR2 in the first trench T71. For example, the active cut 750 may be disposed along the sidewalls and the bottom surface of the first trench T71. For example, the top surface of the active cut 750 may be formed on the same plane as (e.g., may be coplanar with) the top surfaces of the first, second, and third gate capping patterns 731, 732, and 733. The second trench T72 may be formed on the active cut 750, in the first trench T71.

The flowable material layer 760 may fill or be in at least part of the second trench T72. For example, a top surface 760a of the flowable material layer 760 may be formed to be lower than the top surface of the active cut 750 relative to the substrate 100. For example, the top surface 760a of the flowable material layer 760 may be formed to be higher than the top surfaces of the first and second active patterns F71 and F72 relative to the substrate 100. For example, the flowable material layer 760 may not be in contact with the substrate 100 and the first and second active patterns F71 and F72. The flowable material layer 160 may include a flowable insulating material.

The active cut capping pattern 734 may be disposed in the second trench T72. The active cut capping pattern 734 may be disposed on the top surface 760a of the flowable material layer 760, in the second trench T72. For example, the bottom surface of the active cut capping pattern 734 may be in contact with the top surface 760a of the flowable material layer 760, but the present disclosure is not limited thereto. Alternatively, in some embodiments, an airgap may be formed between the top surface 760a of the flowable material layer 760 and the bottom surface of the active cut capping pattern 734.

The first interlayer insulating layer 740 may be disposed on the field insulating layer 105. The first interlayer insulating layer 740 may cover, overlap, or be on the first and second source/drain regions SD71 and SD72. The first interlayer insulating layer 740 may surround the sidewalls of each of the first gate spacers 711, the sidewalls of each of the second gate spacers 712, the sidewalls of each of the third gate spacers 713, the sidewalls of the first gate capping pattern 731, the sidewalls of the second gate capping pattern 732, and the sidewalls of the third gate capping pattern 733.

As used herein, the terms “comprises”, “comprising”, “includes”, “including”, “has”, “having” and any other variations thereof specify the presence of the stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Embodiments of the present disclosure have been described above with reference to the accompanying drawings, but the present disclosure is not limited thereto and may be implemented in various different forms. It will be understood that the present disclosure can be implemented in other specific forms without changing the scope of the present disclosure. Therefore, it should be understood that the embodiments set forth herein are illustrative in all respects and not limiting.

What is claimed is:

1. A semiconductor device comprising:
a substrate;
a first active pattern that extends in a first horizontal direction on the substrate;
a second active pattern that extends in the first horizontal direction on the substrate, wherein the second active pattern is spaced apart from the first active pattern in the first horizontal direction;
a first gate electrode that extends in a second horizontal direction different from the first horizontal direction on the first active pattern;
a second gate electrode that extends in the second horizontal direction on the second active pattern;
a first trench that extends in the second horizontal direction between the first gate electrode and the second gate electrode, wherein the first trench separates the first active pattern and the second active pattern, and at least part of the first trench is in the substrate;
an active cut that extends along sidewalls and a bottom surface of the first trench, wherein the active cut is in contact with each of the first active pattern and the second active pattern;
a second trench on the active cut in the first trench; and
a flowable material layer in at least part of the second trench, wherein the flowable material layer includes a flowable insulating material, and wherein the flowable material layer is not in contact with each of the substrate, the first active pattern, and the second active pattern.

2. The semiconductor device of claim 1, wherein a top surface of the flowable material layer is lower than a top surface of the active cut relative to the substrate.

3. The semiconductor device of claim 1, further comprising:
an active cut capping pattern on the flowable material layer in the second trench, wherein the active cut capping pattern includes a material different from that of the flowable material layer.

4. The semiconductor device of claim 3, wherein a top surface of the active cut capping pattern is coplanar with a top surface of the active cut.

5. The semiconductor device of claim 3, further comprising:
an airgap between a top surface of the flowable material layer and a bottom surface of the active cut capping pattern in the second trench.

6. The semiconductor device of claim 1, further comprising:
a gate capping pattern that extends in the second horizontal direction on a top surface of the first gate electrode,
wherein a top surface of the active cut is coplanar with a top surface of the gate capping pattern.

7. The semiconductor device of claim 1, further comprising:
a third gate electrode on the first and second active patterns, wherein the third gate electrode extends in the second horizontal direction between the first gate electrode and the second gate electrode, and
wherein the first trench extends into the third gate electrode in a vertical direction, the vertical direction being perpendicular to the first and second horizontal directions.

8. The semiconductor device of claim 7, wherein sidewalls of the active cut are in contact with the third gate electrode.

9. The semiconductor device of claim 1, further comprising:
a first plurality of nanosheets spaced apart from one another in a vertical direction on the first active pattern, wherein the first plurality of nanosheets is at least partially surrounded by the first gate electrode, and wherein the vertical direction is perpendicular to the first and second horizontal directions; and
a second plurality of nanosheets spaced apart from one another in the vertical direction on the second active pattern, wherein the second plurality of nanosheets is at least partially surrounded by the second gate electrode.

10. The semiconductor device of claim 9, wherein a top surface of the flowable material layer is higher than a top surface of an uppermost nanosheet of the first plurality of nanosheets relative to the substrate.

11. The semiconductor device of claim 9, wherein a top surface of the flowable material layer is between a bottom surface of a lowermost nanosheet of the first plurality of nanosheets and a top surface of an uppermost nanosheet of the first plurality of nanosheets.

12. The semiconductor device of claim 9, wherein a top surface of the flowable material layer is lower than a bottom surface of a lowermost nanosheet of the first plurality of nanosheets relative to the substrate.

13. A semiconductor device comprising:
a substrate;
a first active pattern that extends in a first horizontal direction on the substrate;
a second active pattern that extends in the first horizontal direction on the substrate, wherein the second active pattern is spaced apart from the first active pattern in the first horizontal direction;
a first gate electrode that extends in a second horizontal direction different from the first horizontal direction on the first active pattern;
a gate capping pattern that extends in the second horizontal direction on a top surface of the first gate electrode;
an active cut spaced apart from the first gate electrode in the first horizontal direction, wherein the active cut separates the first active pattern and the second active pattern, wherein the active cut is in contact with each of the first active pattern and the second active pattern, at least part of the active cut is in the substrate, and a top surface of the active cut is coplanar with a top surface of the gate capping pattern;
a flowable material layer in the active cut, wherein the flowable material layer includes a flowable insulating material, wherein the flowable material layer is not in contact with each of the substrate, the first active pattern, and the second active pattern, and a top surface of the flowable material layer is lower than the top surface of the active cut relative to the substrate; and
an active cut capping pattern on the flowable material layer in the active cut, wherein the active cut capping pattern includes a material different from that of the flowable material layer.

14. The semiconductor device of claim 13, wherein a bottom surface of the active cut capping pattern is lower than a bottom surface of the gate capping pattern relative to the substrate.

15. The semiconductor device of claim 13, wherein at least part of the flowable material layer is in the substrate.

16. The semiconductor device of claim 13, further comprising:
an airgap between the top surface of the flowable material layer and a bottom surface of the active cut capping pattern in the active cut.

17. The semiconductor device of claim 13, further comprising:
a second gate electrode spaced apart from the first gate electrode in the first horizontal direction, wherein the second gate electrode extends in the second horizontal direction on the first and second active patterns, and wherein the second gate electrode is in contact with sidewalls of the active cut in the first horizontal direction.

18. The semiconductor device of claim 13, further comprising:
a first plurality of nanosheets spaced apart from one another in a vertical direction on the first active pattern, wherein the first plurality of nanosheets is at least partially surrounded by the first gate electrode, and wherein the vertical direction is perpendicular to the first and second horizontal directions; and
a second plurality of nanosheets spaced apart from one another in the vertical direction on the first and second active patterns, wherein the second plurality of nanosheets is in contact with sidewalls of the active cut in the first horizontal direction.

19. The semiconductor device of claim 18, wherein the top surface of the flowable material layer is higher than a top surface of an uppermost nanosheet of the first plurality of nanosheets relative to the substrate.

20. A semiconductor device comprising:
a substrate;
a first active pattern that extends in a first horizontal direction on the substrate;
a second active pattern that extends in the first horizontal direction on the substrate, wherein the second active pattern is spaced apart from the first active pattern in the first horizontal direction;
a first plurality of nanosheets spaced apart from one another in a vertical direction perpendicular to the first horizontal direction on the first active pattern;
a second plurality of nanosheets spaced apart from one another in the vertical direction on the second active pattern;
a third plurality of nanosheets spaced apart from one another in the vertical direction on the first and second active patterns;
a first gate electrode that extends in a second horizontal direction different from the first horizontal direction on the first active pattern, wherein the first gate electrode at least partially surrounds the first plurality of nanosheets;
a second gate electrode that extends in the second horizontal direction on the second active pattern, wherein the second gate electrode at least partially surrounds the second plurality of nanosheets;
a third gate electrode that extends in the second horizontal direction on the first and second active patterns, wherein the third gate electrode at least partially surrounds the third plurality of nanosheets;
a first trench that extends into the third gate electrode, the third plurality of nanosheets, and the substrate in the vertical direction, wherein the first trench extends in the second horizontal direction between the first gate electrode and the second gate electrode, and wherein the first trench separates the first active pattern and the second active pattern;
an active cut that extends along sidewalls and a bottom surface of the first trench, wherein the active cut is in contact with each of the first active pattern, the second active pattern, the third gate electrode, and the third plurality of nanosheets;
a second trench on the active cut in the first trench;
a flowable material layer in at least part of the second trench, wherein the flowable material layer includes a flowable insulating material, and wherein the flowable material layer is not in contact with each of the substrate, the first active pattern, and the second active pattern; and
an active cut capping pattern on the flowable material layer in the active cut, wherein the active cut capping pattern includes a material different from that of the flowable material layer.
